(19) United States
(12) Patent Application Publication
(10) Pub. No.: US 2020/0052062 A1
(43) Pub. Date: Feb. 13, 2020

(54) OLED SUBSTRATE STRUCTURE

(71) Applicant: SHENZHEN CHINA STAR OPTOELECTRONICS SEMICONDUCTOR DISPLAY TECHNOLOGY CO., LTD., Shenzhen, Guangdong (CN)

(72) Inventors: Yawei LIU, Shenzhen, Guangdong (CN); Tsungyuan WU, Shenzhen, Guangdong (CN)

(21) Appl. No.: 15/736,506

(22) PCT Filed: Nov. 27, 2017
(86) PCT No.: PCT/CN2017/113053

§ 371 Date: Dec. 14, 2017

(30) Foreign Application Priority Data
Oct. 16, 2017 (CN) 201710963891.4

(51) Int. Cl. H01L 27/32

(52) U.S. Cl. CPC H01L 27/3283; H01L 51/0004; H01L 27/3246

(57) ABSTRACT

An OLED substrate structure including a base substrate (1) and a bank layer (3) disposed on the base substrate (1) is provided; the bank layer (3) includes a plurality of accommodating grooves (31) arranged in array corresponding to a region of an effective display area (AA) of the OLED and a recess (33) arranged surrounding all the accommodating grooves (31) in a region corresponding to the periphery of the effective display area (AA) of the OLED; one of the accommodating grooves (31) corresponds to one pixel (P), applied to accommodate an OLED organic functional layer (D); due to the disposition of the recess (33), the OLED substrate structure of the disclosure can make the ambient atmosphere around the pixels in each area uniform when the OLED device is fabricated by printing, and volatilize the solvent uniformly to improve an uniformity of a film thickness of the OLED organic functional layer.

### RELATED APPLICATIONS

The present application is a National Phase of International Application Number PCT/CN2017/113053, filed on Nov. 27, 2017, and claims the priority of China Application 201710963891.4, filed Oct. 16, 2017.

### FIELD OF THE DISCLOSURE

The disclosure relates to the field of display technology, and in particular, to an OLED substrate structure.

### BACKGROUND

The organic light emitting diode (OLED) display apparatus is recognized by the industry as the most promising display device due to many advantages such as self-luminousness, low driving voltage, high luminous efficiency, short response time, high resolution and contrast, viewing angle nearly 180°, wide temperature range, and capability of achieving the flexible display and large-area panchromatic display.

The OLED generally includes a substrate, an anode disposed on the substrate, a hole injection layer disposed on the anode, a hole transport layer disposed on the hole injection layer, and a light emitting layer disposed on the hole transport layer, an electron transport layer disposed on the light emitting layer, and a cathode disposed on the electron transport layer. The light-emitting principle of an OLED display device is that semiconductor materials and organic light-emitting materials emit light through carrier injection and recombination under an electric field. Specifically, an OLED display device generally adopts an ITO pixel electrode and a metal electrode as an anode and a cathode of the device respectively. Under a certain voltage, electrons and holes are injected from the cathode and the anode into the electron transport layer and the hole transport layer respectively. the electrons and holes migrate to the light emitting layer through the electron transport layer and the hole transport layer respectively, and meet in the light emitting layer to form excitons to excite the light-emitting molecules, which emit visible light through radiation relaxation.

The fabricating methods of the existing OLED device are mainly divided into a vacuum thermal evaporation and a solution film-forming method, and the solution film-forming method is to firstly coat the solution containing the OLED organic functional layer material on the substrate, and then remove the solvent in the solution by a vacuum drying process, so that the solid substance in the solution forms a thin film on the substrate. Specifically, the solution film-forming method is subdivided into the methods such as spin coating, nozzle printing, and ink-jet printing method.

Referring to FIGS. 1 and 2, a conventional OLED substrate includes a base substrate 100 and a bank layer 300 disposed on the base substrate 100. The bank layer 300 includes a plurality of accommodating grooves 301 arranged in an array in the effective display area AA of the ° LED; one of the accommodating grooves 301 corresponds to one pixel P, applied to accommodate an OLED organic functional layer. When the OLED device is fabricated by printing, the accommodating groove 301 is used for accommodating the solution containing the OLED organic functional layer material, Since the atmosphere surrounding the pixel P at the edge of the effective display area AA is not uniform, the solvent on the side close to the air is volatilized quickly, thereby causing the solution in the pixel P to flow toward the air side for compensating, so that the film thickness of the OLED organic functional layer on the air side is thicker; and the atmosphere surrounding the pixel P in the middle of the effective display area AA is relatively uniform and the solvent is volatilized slowly and uniformly, and the thickness uniformity of the resulting OLED organic functional layer is better.

Since the uniformity of the film thickness distribution of the organic functional layer of the OLED directly affects the uniformity of light emission in the pixel P and the lifetime of the OLED device, it is necessary to improve the existing OLED substrate structure.

### SUMMARY

The object of the disclosure is to provide an OLED substrate capable of making the ambient atmosphere around the pixels in each area uniform when the OLED device is fabricated by printing, and the solvent is volatilized uniformly to improve a uniformity of a film thickness of the OLED organic functional layer.

In order to achieve the object, the disclosure provides an OLED substrate structure, including a base substrate and a bank layer disposed on the base substrate; and the bank layer includes a plurality of accommodating grooves arranged in array in a region corresponding to an effective display area of the OLED and a recess arranged surrounding all the accommodating grooves in a region corresponding to the periphery of the effective display area of the OLED;

and one of the accommodating grooves corresponds to one pixel, applied to accommodate an OLED organic functional layer.

Optionally, the recess is in a rectangular frame shape with four sides communicated with each other.

Optionally, the recess includes a first recess and a second recess, and the first recess and the second recess are combined in a rectangular frame shape.

The first recess occupies three communicating sides of the rectangular frame shape and the second recess occupies a remaining side of the rectangular frame shape.

Or the first recess occupies two communicating sides of the rectangular frame shape, and the second recess occupies other two communicating sides of the rectangular frame shape.

Optionally, the recess includes a first recess, a second recess and a third recess, and the first recess, the second recess, and the third recess are combined in a rectangular frame shape; the first recess occupies two communicating sides of the rectangular frame shape, and the second recess and the third recess occupy other two communicating sides of the rectangular frame shape respectively.

Optionally, the recess includes a first recess, a second recess, a third recess, and a fourth recess; the first recess, the second recess, the third recess, and the fourth recess are combined in a rectangular frame shape; the first recess, the second recess, the third recess, and the fourth recess respectively occupy one of the sides of the rectangular frame shape.

Further, each of the first recess, the second recess, the third recess, and the fourth recess includes at least two independent branch recesses.

The recess has a width of 0.1 mm to 50 mm.

A distance between the recess and a corresponding accommodating groove located at the outermost edge of the effective display area of the OLED is 0.01 mm to 10 mm.

The disclosure further provides an OLED substrate structure including a base substrate and a bank layer disposed on the base substrate; and the bank layer includes a plurality of accommodating grooves arranged in array in a region corresponding to an effective display area of the OLED and a recess arranged surrounding all the accommodating grooves in a region corresponding to the periphery of the effective display area of the OLED;

one of the accommodating grooves corresponds to one pixel, applied to accommodate an OLED organic functional layer;

the recess includes a first recess; a second recess; a third recess, and a fourth recess; the first recess, the second recess, the third recess, and the fourth recess are combined in the rectangular frame shape. Each of the first recess, the second recess, the third recess, and the fourth recess occupies one of the sides of the rectangular frame shape; and

each of the first recess, the second recess, the third recess, and the fourth recess includes at least two independent branch recesses;

the recess has a width of 0.1 mm to 50 mm; and

a distance between the recess and a corresponding accommodating groove located at the outermost edge of the effective display area of the OLED is 0.01 mm to 10 mm.

The beneficial effect of the disclosure is that the disclosure provides an OLED substrate structure; by disposing a recess to contain a solution containing an OLED organic functional layer material or a simple solvent when the OLED device is fabricated by printing, ensures that the atmosphere around the pixels in each area is more uniform in particular around the pixels at the edges of the effective display area of the OLED, thereby volatilizing the solvent uniformly to improve an uniformity of a film thickness of the OLED organic functional layer.

### BRIEF DESCRIPTION OF THE DRAWINGS

For further understanding of the features and technical contents of the disclosure, reference should be made to the following detailed description and accompanying drawings of the disclosure. However, the drawings are for reference only and are not intended to limit the disclosure.

In the drawings,

FIG. 1 is a cross-sectional view of a conventional OLED substrate structure in a process of fabricating an OLED device by printing;

FIG. 2 is a schematic top view of the conventional OLED substrate structure;

FIG. 3 is a schematic top view of a first embodiment of an OLED substrate structure of the disclosure;

FIG. 4 is a cross-sectional view corresponding to E-E in FIG. 3;

FIG. 5 is a schematic top view of a second embodiment of the OLED substrate structure of the disclosure;

FIG. 6 is a cross-sectional view corresponding to E-E in FIG. 5;

FIG. 7 is a schematic top view of a third embodiment of the OLED substrate structure of the disclosure;

FIG. 8 is a cross-sectional view corresponding to E-E in FIG. 7;

FIG. 9 is a schematic top view of a fourth embodiment of the OLED substrate structure of the disclosure;

FIG. 10 is a cross-sectional view corresponding to E-E in FIG. 9;

FIG. 11 is a schematic top view of a fifth embodiment of the OLED substrate structure of the disclosure;

FIG. 12 is a cross-sectional view corresponding to E-E in FIG. 11;

FIG. 13 is a schematic top view of a sixth embodiment of an OLED substrate structure of the disclosure; and

FIG. 14 is a cross-sectional view corresponding to E-E in FIG. 13.

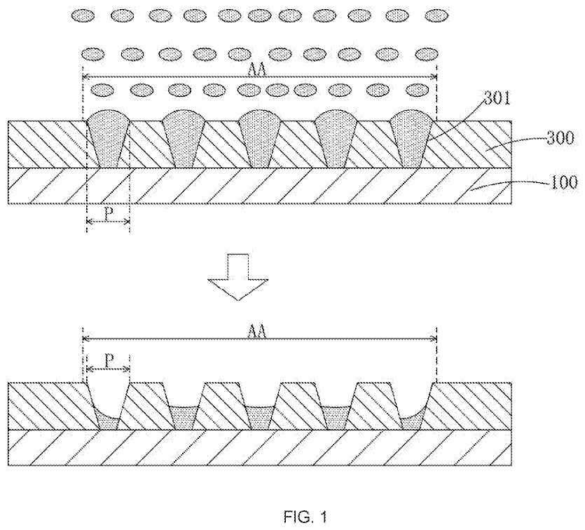

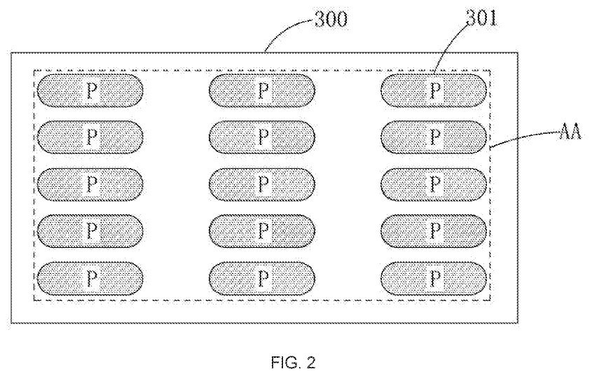

### DETAILED DESCRIPTION OF PREFERRED EMBODIMENTS

To further illustrate the technical means adopted by the disclosure and the effects thereof, the following describes in detail the preferred embodiments of the disclosure and the accompanying drawings.

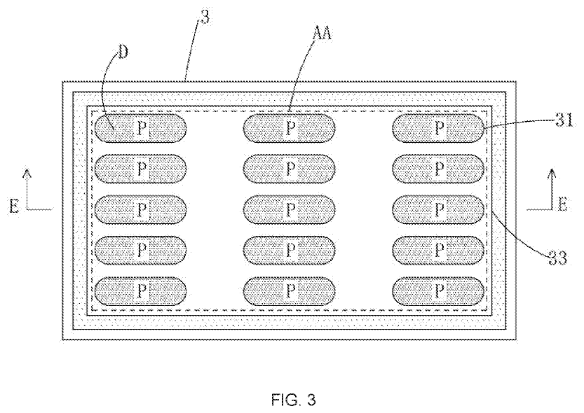

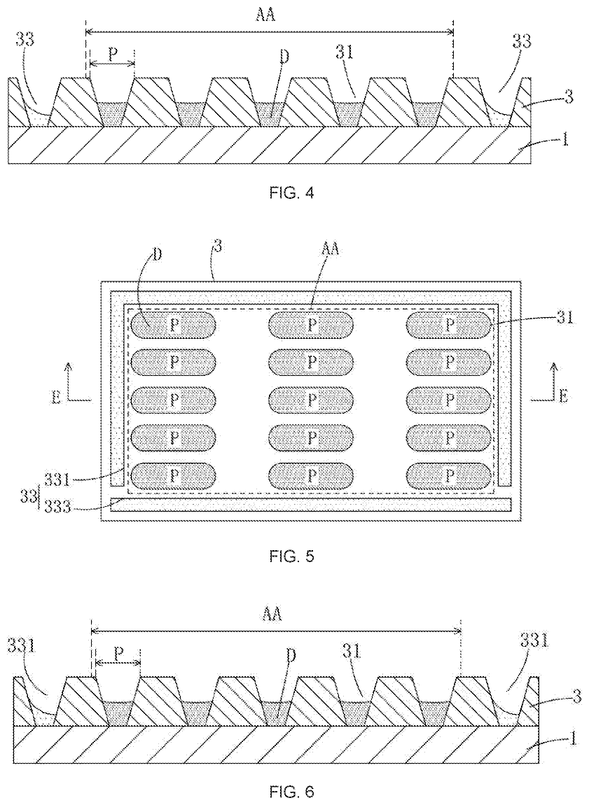

The disclosure provides an OLED substrate structure. Please refer to FIGS. 3 and 4 together, a first embodiment of an OLED substrate structure of the disclosure includes a base substrate 1 and a bank layer 3 disposed on the base substrate 1. The bank layer 3 includes a plurality of accommodating grooves 31 arranged in array in a region corresponding to an effective display area AA of the OLED and a recess 33 arranged surrounding all the accommodating grooves 31 in a region corresponding to the periphery of the effective display area AA of the OLED. One of the accommodating grooves 31 corresponds to one pixel P, applied to accommodate an OLED organic functional layer D.

As shown in FIGS. 3 and 4, in the first embodiment; the recess 33 has a rectangular frame shape with four sides communicated with each other.

Specifically, the recess 33 has a width of 0.1 mm to 50 mm; a distance between the recess 33 and a corresponding accommodating groove 31 located at the outermost edge of the effective display area AA of the OLED is 0.01 mm to 10 mm.

When the OLED device is fabricated by printing, the recess 33 is used for accommodating a solution containing the OLED organic functional layer material or a simple solvent; in this way, the pixel P corresponding to the edge of the effective display area of the OLED is close to the recess 33 instead of the air side, and the solution containing the OLED organic functional layer material or a simple solvent in the recess 33 also generates an atmosphere, so the atmosphere around the pixel P corresponding to the edge of the effective display area AA of the OLED is relatively uniform, thereby volatilizing the solvent uniformly to improve an uniformity of a film thickness of the OLED organic functional layer.

Please refer to FIGS. 5 and 6 together, which are the second embodiment of the OLED substrate structure of the disclosure. The difference between the second embodiment and the first embodiment in that the recess 33 includes a first recess 331 and a second recess 333, and the first recess 331 and the second recess 333 are combined in a rectangular frame shape; and the first recess 331 occupies three communicating sides of the rectangular frame shape, and the second recess 333 occupies a remaining side of the rectangular frame shape. The remaining structures and the functions of the recess 33 are the same as those in the first embodiment, and will not be repeatedly described herein.

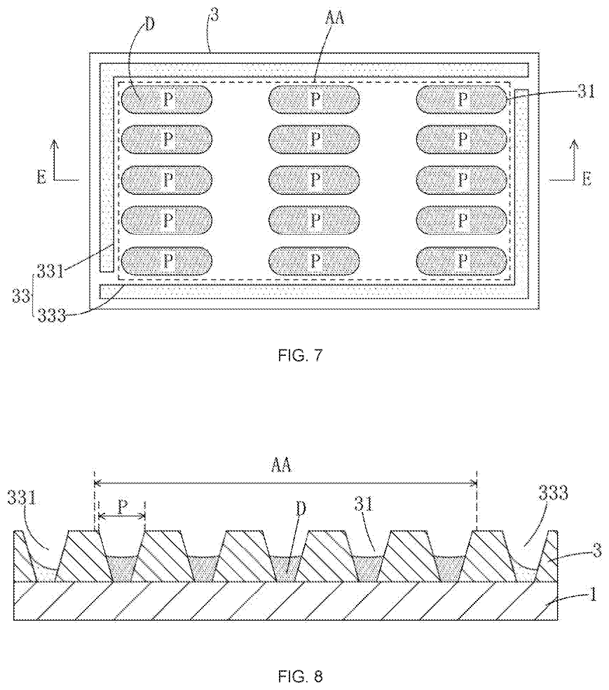

Please refer to FIGS. 7 and 8 together, which are the third embodiment of the OLED substrate structure of the disclosure. The difference between the third embodiment and the first embodiment is that the recess 33 includes a first recess 331 and a second recess 333, and the first recess 331 and the second recess 333 are combined in a rectangular frame shape; and the first recess 331 occupies two communicating sides of the rectangular frame shape, and the second recess 333 occupies other two communicating sides of the rectangular frame shape. The remaining structures and the functions of the recess 33 are the same as those in the first embodiment, and will not be repeatedly described herein.

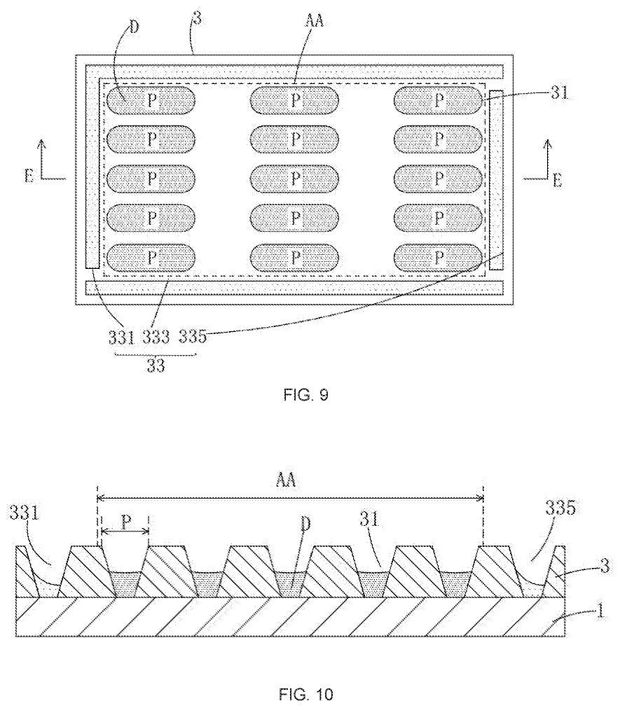

Please refer to FIGS. 9 and 10 together, which is a fourth embodiment of the OLED substrate structure of the disclosure. The difference between the fourth embodiment and the first embodiment in that the recess 33 includes a first recess 331, a second recess 333, and a third recess 335, and the first recess 331, the second recess 333, and the third recess 335 are combined in a rectangular frame shape; the first recess 331 occupies two communicating sides of the rectangular frame shape, and the second recess 333 and the third recess 335 occupies other two communicating sides of the rectangular frame shape respectively. The remaining structures and the functions of the recess 33 are the same as those in the first embodiment, and will not be repeatedly described herein.

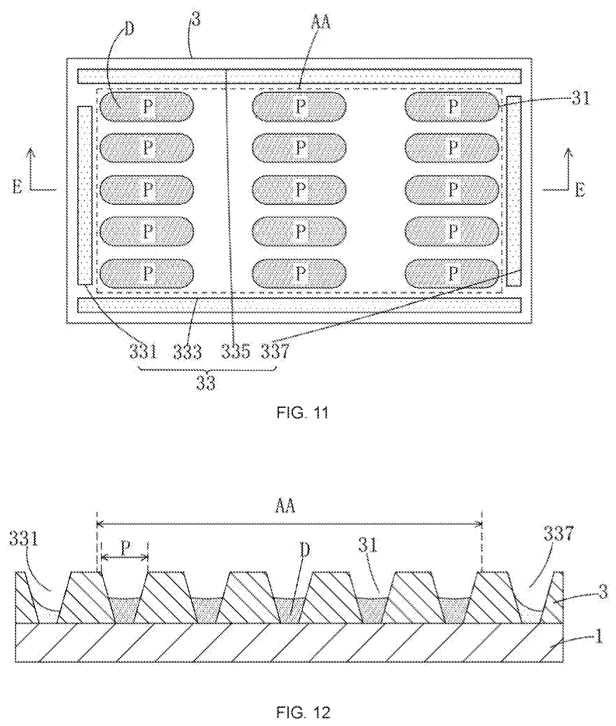

Please refer to FIGS. 11 and 12 together, which are the fifth embodiment of the OLED substrate structure of the disclosure. The difference between the fifth embodiment and the first embodiment in that the recess 33 includes the first recess 331, the second recess 333, the third recess 335, and a fourth recess 337, and the first recess 331, the second recess 333, the third recess 335, and the fourth recess 337 are combined in a rectangular frame shape; and the first recess 331, the second recess 333, the third recess 335, and the fourth recess 337 respectively occupy one of the sides of the rectangular frame shape. The remaining structures and the functions of the recess 33 are the same as those in the first embodiment, and will not be repeatedly described herein.

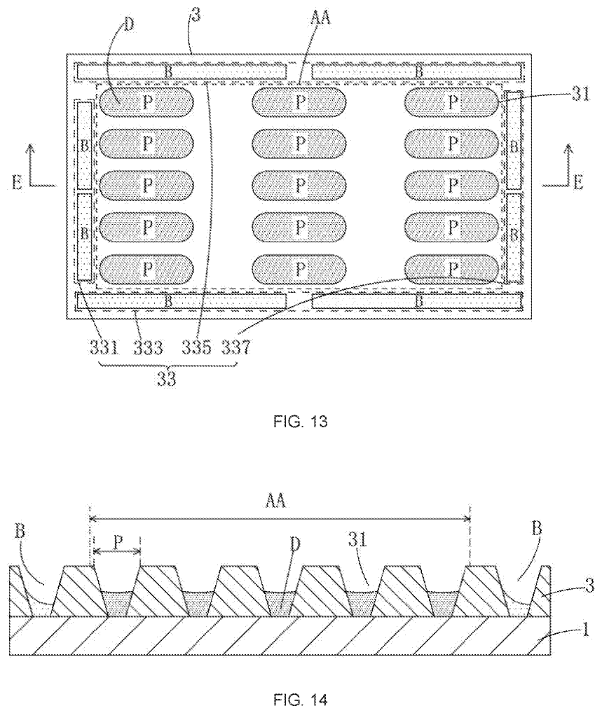

Please refer to FIGS. 13 and 14, which are the sixth embodiment of the OLED substrate structure of the disclosure. The sixth embodiment is an improvement of the fifth embodiment, and the improvement is that each of the first recess 331, the second recess 333, the third recess 335, and the fourth recess 337 includes at least two independent branch recesses B. The remaining structures and the functions of the recess 33 are the same as those in the fifth embodiment, and will not be repeatedly described herein.

The above design of the OLED substrate structure can also be applied to a Quantum Dot Printed Display (QLED) substrate.

To sum up, an OLED substrate structure, by disposing a recess to contain a solution containing an OLED organic functional layer material or a simple solvent when the OLED device is fabricated by printing, ensures that the atmosphere around the pixels in each area is more uniform especially around the pixels at the edges of the effective display area of the OLED, thereby volatilizing the solvent uniformly to improve a uniformity of a film thickness of the OLED organic functional layer.

In view of the above, those skilled in the art can make various other corresponding changes and modifications according to the technical solutions and technical solutions of the disclosure, and all such changes and modifications shall fall within the protection scope of the claims of the disclosure range.

What is claimed is:

1. An OLED substrate structure, comprising:
a base substrate and
a bank layer disposed on the base substrate;
wherein the bank layer comprises a plurality of accommodating grooves arranged in array in a region corresponding to an effective display area of the OLED and a recess arranged surrounding all the accommodating grooves in a region corresponding to a periphery of the effective display area of the OLED;
wherein one of the accommodating grooves corresponds to one pixel, applied to accommodate an OLED organic functional layer.

2. The OLED substrate structure according to claim 1, wherein the recess comprises a rectangular frame shape with four sides communicated with each other.

3. The OLED substrate structure as claimed in claim 1, wherein the recess comprises a first recess and a second recess, and the first recess and the second recess are combined in a rectangular frame shape.

4. The OLED substrate structure according to claim 3, wherein the first recess occupies three communicating sides of the rectangular frame shape, and the second recess occupies a remaining side of the rectangular frame shape.

5. The OLED substrate structure according to claim 3, wherein the first recess occupies two communicating sides of the rectangular frame shape, and the second recess occupies other two communicating sides of the rectangular frame shape.

6. The OLED substrate structure according to claim 1, wherein the recess comprises a first recess, a second recess, and a third recess, and the first recess, the second recess, and a third recess are combined in a rectangular frame shape; the first recess occupies two communicating sides of the rectangular frame shape, and the second recess and the third recess occupy other two communicating sides of the rectangular frame shape respectively.

7. The OLED substrate structure according to claim 1, wherein the recess comprises a first recess, a second recess, a third recess, and a fourth recess; and the first recess, the second recess, the third recess, and the fourth recess are combined in a rectangular frame shape; the first recess, the second recess, the third recess, and the fourth recess respectively occupy one of sides of the rectangular frame shape.

8. The OLED substrate structure according to claim 7, wherein each of the first recess, the second recess, the third recess, and the fourth recess comprises at least two independent branch recesses.

9. The OLED substrate structure according to claim 1, wherein the recess has a width of 0.1 mm to 50 mm.

10. The OLED substrate structure according to claim 1, wherein a distance between the recess and a corresponding accommodating groove located at the outermost edge of the effective display area of the OLED is 0.01 mm to 10 mm.

11. An OLED substrate structure, comprising:
a base substrate and
a bank layer disposed on the base substrate;
wherein the bank layer comprises a plurality of accommodating grooves arranged in array in a region corresponding to an effective display area of the OLED and a recess arranged surrounding all the accommodating grooves in a region corresponding to a periphery of the effective display area of the OLED;
wherein one of the accommodating grooves corresponds to one pixel, applied to accommodate an OLED organic functional layer;
wherein the recess comprises a first recess, a second recess, a third recess, and a fourth recess; the first recess, the second recess, the third recess, and the fourth recess are combined in a rectangular frame shape; and the first recess, the second recess, the third recess, and the fourth recess respectively occupy one of sides of the rectangular frame shape;
wherein each of the first recess, the second recess, the third recess, and the fourth recess comprises at least two independent branch recesses;
wherein the recess has a width of 0.1 mm to 50 mm;
wherein a distance between the recess and a corresponding accommodating groove located at the outermost edge of the effective display area of the OLED is 0.01 mm to 10 mm.
